(19) United States
(12) Patent Application Publication
(10) Pub. No.: US 2026/0074486 A1
(43) Pub. Date: Mar. 12, 2026

(54) VERTICAL-CAVITY SURFACE-EMITTING LASER, LASER ARRAY AND LIGHT-EMITTING DEVICE

(71) Applicant: VERTILITE CO., LTD., Changzhou (CN)

(72) Inventors: Dong LIANG, Changzhou (CN); Cheng ZHANG, Changzhou (CN); Song LIU, Changzhou (CN); Huijie LI, Changzhou (CN); Shouzhu NIU, Changzhou (CN)

(21) Appl. No.: 19/393,002

(22) Filed: Nov. 18, 2025

Related U.S. Application Data
(63) Continuation of application No. PCT/CN2024/134137, filed on Nov. 25, 2024.
(60) Provisional application No. 63/626,171, filed on Jan. 29, 2024.

(30) Foreign Application Priority Data
Jul. 11, 2024 (CN) 202410929560.9

(51) Int. Cl. H01S 5/183; H01S 5/34; H01S 5/42

(52) U.S. Cl. CPC H01S 5/18361; H01S 5/3416; H01S 5/423

(57) ABSTRACT

Disclosed are a vertical-cavity surface-emitting laser (VCSEL), a laser array, and a light-emitting device. The VCSEL includes an N-type substrate and an upper distributed Bragg reflector (DBR), and an N-type buffer layer, a first tunnel junction, a P-type DBR, an active layer, a second tunnel junction, a P-type metal contact layer, and a cathode electrode stacked sequentially along a direction perpendicular to a front side of the N-type substrate and arranged on the front side of the N-type substrate. The first tunnel junction is configured to reverse carriers in the N-type buffer layer to carriers of opposite conductivity type. The second tunnel junction is configured to reverse carriers in the upper DBR to carriers of opposite conductivity type. The upper DBR is positioned between the active layer and the P-type metal contact layer. An anode electrode is arranged on a back side of the N-type substrate.

### CROSS-REFERENCE TO RELATED APPLICATIONS

This application is a continuation application of international patent application No. PCT/CN2024/134137, filed on Nov. 25, 2024, which claims priority to U.S. patent application Ser. No. 63/626,171, entitled “A VCSEL STRUCTURE CONTAINING TWO TUNNEL JUNCTIONS”, filed with the United States Patent Office on Jan. 29, 2024, and Chinese patent application No. 202410929560.9, entitled “VERTICAL-CAVITY SURFACE-EMITTING LASER, LASER ARRAY, AND LIGHT-EMITTING DEVICE”, filed with the China National Intellectual Property Administration on Jul. 11, 2024, and the contents of which are hereby incorporated herein by reference in their entireties.

### TECHNICAL FIELD

The present disclosure relates to the field of semiconductor lasers, and particularly to a vertical-cavity surface-emitting laser, a laser array, and a light-emitting device.

### BACKGROUND

A Vertical-Cavity Surface-Emitting Laser (VCSEL) is a type of semiconductor laser, and has a basic structure primarily including an active layer and Distributed Bragg Reflectors (DBRs) that have a function of optical feedback.

### SUMMARY

In a first aspect, in some embodiments, the present disclosure provides a vertical-cavity surface-emitting laser (VCSEL) including an N-type substrate, an upper distributed Bragg reflector (DBR), an N-type buffer layer, a first tunnel junction, a P-type DBR, an active layer, a second tunnel junction, a P-type metal contact layer, and a cathode electrode. The N-type buffer layer, the first tunnel junction, the P-type DBR, the active layer, the second tunnel junction, the P-type metal contact layer, and the cathode electrode are stacked sequentially along a direction perpendicular to a front side of the N-type substrate and arranged on the front side of the N-type substrate. The first tunnel junction is configured to reverse carriers in the N-type buffer layer to carriers of opposite conductivity type. The second tunnel junction is configured to reverse carriers in the upper DBR to carriers of opposite conductivity type. The upper DBR is positioned between the active layer and the P-type metal contact layer and associated with the second tunnel junction. An anode electrode is arranged on a back side of the N-type substrate away from the N-type buffer layer.

In some embodiments, the active layer includes an object stacked structure. The object stacked structure includes a P-type semiconductor layer, a quantum well layer, and an N-type semiconductor layer sequentially stacked along the direction perpendicular to the front side the N-type substrate; the P-type semiconductor layer is adjacent to the P-type DBR. The quantum well layer includes at least one quantum well.

In some embodiments, a central cross-section of the first tunnel junction is positioned within a node region of a standing wave electric field of the VCSEL. The node region is [p−λ/8, p+λ/8], where p represents a node z-axial position, λ represents a wavelength of a standing wave, and a positive direction of a z-axis is a direction perpendicular to the front side of the N-type substrate and pointing toward the first tunnel junction.

In some embodiments, a central cross-section of a quantum well region of the quantum well layer is positioned within an antinode region of a standing wave electric field of the VCSEL. The antinode region is [z−λ/8, z+λ/8], where z represents an antinode z-axial position, λ represents a wavelength of a standing wave, and a positive direction of a z-axis is a direction perpendicular to the front side of the N-type substrate and pointing toward the first tunnel junction.

In some embodiments, the active layer includes a plurality of object stacked structures sequentially stacked along the direction perpendicular to the front side of the N-type substrate. Adjacent object stacked structures are connected via an interlayer tunnel junction. In each two adjacent object stacked structures, the N-type semiconductor layer of one object stacked structure is adjacent to the P-type semiconductor layer of the other object stacked structure.

In some embodiments, a central cross-section of the interlayer tunnel junction is positioned within the node region of the standing wave electric field of the VCSEL. The central cross-section of the interlayer tunnel junction is parallel to the top surface of the substrate. The node region is [p−λ/8, p+λ/8], where p represents a node z-axial position, λ represents a wavelength of a standing wave, and a positive direction of a z-axis is a direction perpendicular to the front side of the N-type substrate and pointing toward the first tunnel junction.

In some embodiments, the upper DBR is a P-type distributed Bragg reflective layer positioned between the second tunnel junction and the P-type metal contact layer.

In some embodiments, the upper DBR is an N-type DBR positioned between the active layer and the second tunnel junction.

In some embodiments, the upper DBR includes stacked multiple second reflective layers. Each of the multiple second reflective layers includes a third reflective sub-layer and a fourth reflective sub-layer with different refractive indices. In each two adjacent second reflective layers, the third reflective sub-layer of one second reflective layer and the fourth reflective sub-layer of the other second reflective layer are adjacent.

In some embodiments, material of each third reflective sub-layer and material of each fourth reflective sub-layer include aluminum gallium arsenide, and an aluminum composition in each third reflective sub-layer and an aluminum composition in each fourth reflective sub-layer are different.

In some embodiments, the material of each third reflective sub-layer is AlₓGa₁₋ₓ As, where x<0.1. The material of each fourth reflective sub-layer is AlₓGa₁₋ₓAs, where x>0.9.

In some embodiments, the upper DBR includes an N-type distributed Bragg reflective sub-layer positioned between the active layer and the second tunnel junction, and a P-type distributed Bragg reflective sub-layer positioned between the second tunnel junction and the P-type metal contact layer.

In some embodiments, the P-type DBR includes stacked multiple first reflective layers. Each of the multiple first reflective layers includes a first reflective sub-layer and a second reflective sub-layer with different refractive indices. In each two adjacent first reflective layers, the first reflective sub-layer of one first reflective layer and the second reflective sub-layer of the other first reflective layer are adjacent.

In some embodiments, a material of each first reflective sub-layer includes indium gallium phosphide, and a lattice constant of compound in each second reflective sub-layer is greater than a lattice constant of the indium gallium phosphide.

In some embodiments, the material of each first reflective sub-layer includes In_{y}Ga_{1-y}P, where y∈ [0, 0.48]. The material of each second reflective sub-layer includes AlₓGa₁₋ₓAs, where x>0.9 In some embodiments, the N-type substrate is made of semiconductor material, insulative material, semi-insulative material, or any combination thereof.

In a second aspect, in some embodiments, the present provides a laser array, including a plurality of VCSELs of any one of the embodiments above arranged in rows and columns. VCSELs in the same row are connected to a corresponding row selection line. VCSELs in the same column are connected to a corresponding column selection line. VCSELs in different rows are connected to different row selection lines, respectively. VCSELs in different columns are connected to different column selection lines, respectively. A VCSEL connected to a selected row selection line and a selected column selection line is activated by selecting the row selection line and the column selection line.

In some embodiments, the plurality of VCSELs arranged in rows and columns shares an anode electrode. Cathode electrodes of any adjacent VCSELs are insulative to each other.

In some embodiments, an isolation structure is arranged between the adjacent VCSELs, and the isolation structure is adapted to extend in the direction perpendicular to the front side of the N-type substrate to the top surface of the P-type DBR.

In a third aspect, in some embodiments, the present disclosure provides a light-emitting device, including the VCSEL of any one of the embodiments above.

In a third aspect, in some embodiments, the present disclosure provides light-emitting device, including the laser array of any one of the embodiments above.

Details in one or more embodiments are provided in the following accompany drawings and description. Other features, objectives, and advantages of the present disclosure will become apparent from the description, the accompanying drawings, and the claims.

### BRIEF DESCRIPTION OF THE DRAWINGS

To illustrate the technical solutions of embodiments of the present disclosure more clearly, the drawings to be used in describing the embodiments shall be briefly introduced below. Obviously, the drawings in the following description merely involve some embodiments of the present disclosure. For those skilled in the art, additional drawings of other embodiments can be obtained based on these drawings without inventive efforts.

FIG. 1a shows a schematic longitudinal-sectional view of a vertical-cavity surface-emitting laser (VCSEL) according to an embodiment of the present disclosure.

FIG. 1b shows a schematic longitudinal-sectional view of a VCSEL according to another embodiment of the present disclosure.

FIG. 1c shows a schematic longitudinal-sectional view of a VCSEL according to yet another embodiment of the present disclosure.

FIG. 1d shows a schematic longitudinal-sectional view of a VCSEL according to yet another embodiment of the present disclosure.

FIG. 1e shows a schematic longitudinal-sectional view of a VCSEL according to yet another embodiment of the present disclosure.

FIG. 2 shows a schematic top view of a laser array according to an embodiment of the present disclosure.

FIG. 3 shows a schematic longitudinal-sectional view of a laser array according to another embodiment of the present disclosure, where FIG. 3 is a schematic longitudinal-sectional view along a direction AA′ shown in FIG. 2.

FIG. 4 shows a schematic flowchart of a VCSEL fabrication method according to an embodiment of the present disclosure.

### DETAILED DESCRIPTION OF THE EMBODIMENTS

To facilitate understanding of the present disclosure, the present disclosure will be described more comprehensively with reference to the drawings. Embodiments of the present disclosure are shown in the drawings. However, the present disclosure may be implemented in multiple distinct embodiments which are not limited to the embodiments described herein. In contrast, these embodiments are provided to make the disclosure of the present disclosure more thorough and comprehensive.

Unless otherwise defined, all technical and scientific terms used herein have the same meanings as commonly understood by those skilled in the art of the technical field of the present disclosure. The terms used in the specification of the present disclosure are for the purpose of describing specific embodiments only and are not intended to limit the present disclosure. The term “and/or”as used herein includes arbitrary and all combinations of one or more related listed items.

It should be understood that, when an element or a layer is referred to as being “on”, “adjacent to”, “connected to”, or “coupled to” another element or layer, it can be directly on, adjacent to, connected to, or coupled to the other element or layer, or an intervening element or layer may be present. In contrast, when an element is referred to as being “directly on”, “directly adjacent to”, “directly connected to”, or “directly coupled to” another element or layer, no intervening elements or layers are present. It should be understood that, although terms such as “first”, “second”, and “third” can be used to describe various elements, components, regions, layers, and/or parts, these elements, components, regions, layers, and/or parts should not be limited by these terms. These terms are only used to distinguish an element, a component, a region, a layer, or a part from another. Thus, without departing from the teachings of the present disclosure, a first element, a first component, a first region, a first layer, or a first part discussed below could be termed a second element, a second component, a second region, a second layer, or a second part.

Spatial relationship terms such as “beneath”, “below”, “lower”, “under”, “above”, and “upper” can be used herein for convenience to describe the relationship of an element or feature to another element or feature as illustrated in the drawings. It should be understood that, these terms are intended to include different orientations of a device in use or operation in addition to orientations shown in the drawings. For example, if the device in the drawings is inverted, an element or a feature described as “below” or “under” another element or another feature would then be oriented “above” the other element or feature. Thus, the terms like “below” and “under” can include both upward and downward orientations. The device can be otherwise oriented (rotated 90 degrees or at other orientations), and the spatial descriptive terms used herein can be interpreted accordingly.

The terms used herein are for the purpose of describing specific embodiments only and are not intended to limit the present disclosure. As used herein, the singular forms “a”, “an”, and “the” are intended to include the plural forms as well, unless the context clearly indicates otherwise. It should also be understood that the terms like “consist of” and/or “include” when used in the specification, specify the presence of features, integers, steps, operations, elements, and/or components, but not exclude the presence or addition of one or more other features, integers, steps, operations, elements, components, and/or groups. As used herein, the term “and/or” includes arbitrary and all combinations of the related listed items.

Embodiments of the application are described herein with reference to schematic sectional views of ideal embodiments (and intermediate structures) of the present disclosure. As such, variations from the shown shapes due to, for example, manufacturing techniques and/or tolerances, are to be anticipated. Thus, the embodiments of the present disclosure should not be limited to the specific shapes of regions shown herein but include deviations in shapes due to, for example, manufacturing. Accordingly, the regions shown in the drawings are illustrative, and shapes of thereof are not intended to illustrate actual shapes of the regions of the device and are not intended to limit the scope of the present disclosure.

A multilayer structure described in an embodiment of the present disclosure may be formed layer-by-layer or integrally, and adjacent two layers in the structure may be in contact with each other or spaced apart.

In an embodiment of the present disclosure, being perpendicular to a substrate may refer to being perpendicular to an upper surface substrate, and being parallel to a substrate may refer to being parallel to an upper surface of a substrate. The upper surface of the substrate is the front side of the substrate.

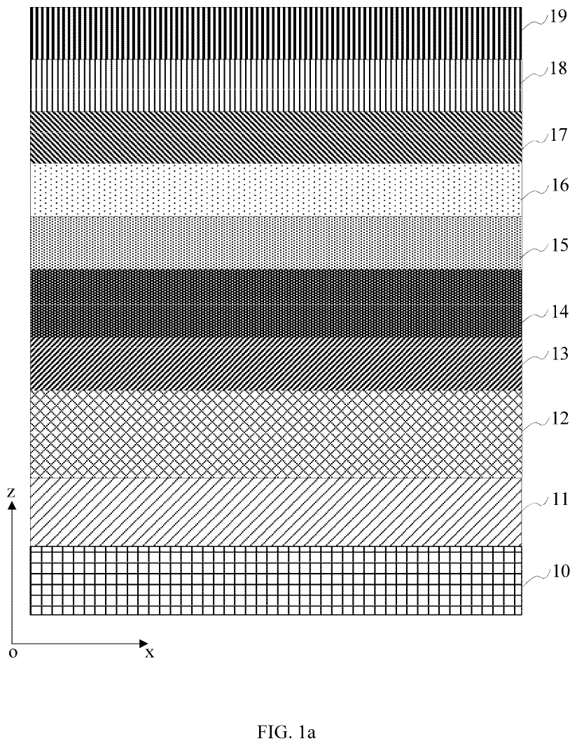

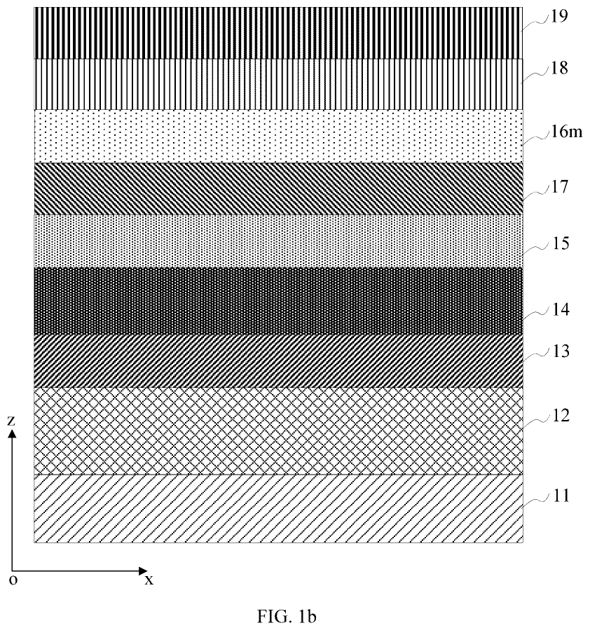

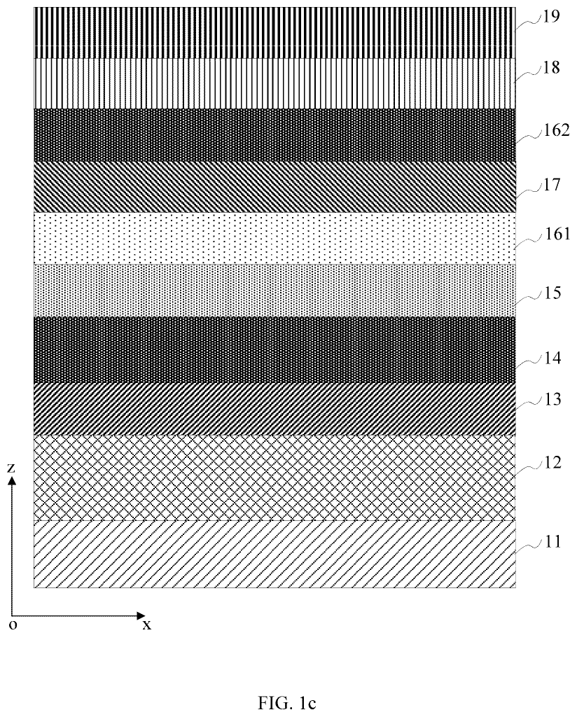

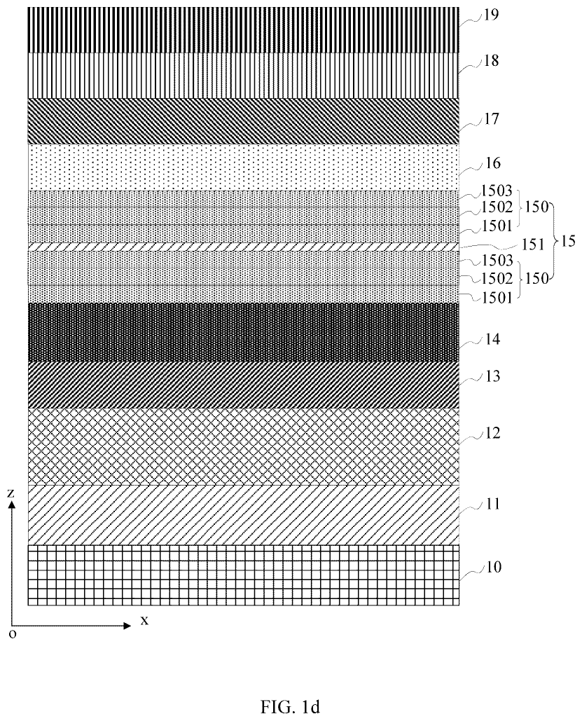

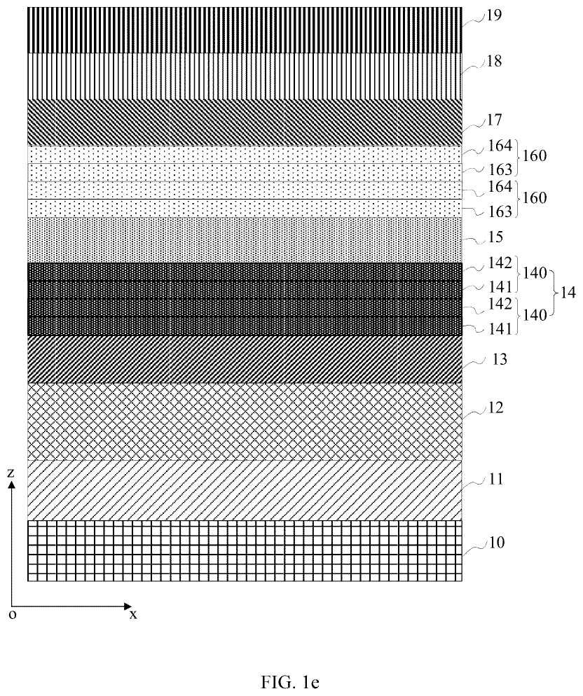

Referring to FIGS. 1a to 1e, and FIGS. 2 to 3, it should be noted that the drawings provided in the embodiment are merely schematic illustrations of the basic concepts of the present disclosure. Although only components relevant to the present disclosure are shown in the drawings, and they are not drawn according to the number, shape, or size thereof in actual implementation, and the form, number, or proportion of the components in the actual implementation can be arbitrarily changed, and the component layout may be more complex.

A basic structure of the VCSEL primarily includes an active layer and Distributed Bragg Reflectors (DBRs) that have a function of optical feedback. The active layer is arranged between DBRs at two sides, which collectively form a Fabry-Perot resonant cavity. A pump source generates optical gain by spontaneous radiation through a gain medium in the active layer. Light waves within the resonant cavity reflect between top and bottom DBRs to form a stable standing wave, which is continuously amplified by stimulated radiation, ultimately forming a laser light.

Typically, the upper and lower reflectors of a VCSEL are doped as P-type and N-type materials, respectively, forming a diode junction.

In conventional VCSELs, the cathode for applying a low potential voltage is typically positioned on the back side of the substrate, while the anode for applying a high potential voltage is generally positioned on the front side of the substrate, thus making it difficult to adopt a common-anode driving mode and limiting the reduction in the size of the driver system, and further hindering the use of N-type transistors having a relatively high response speed, restricting the applications of the VCSELs in high-frequency and high-speed driving field.

With respect to MOSFETs, the performance of an N-channel transistor is generally superior to that of a P-channel transistor. For example, as the electron mobility is higher than the hole mobility, the N-channel transistor has a relatively high response speed and lower resistance. For bipolar junction transistors, an NPN transistor typically has better performance than a PNP transistor. Therefore, N-channel transistors or NPN transistors are used to drive a VCSEL or a VCSEL array, thus improving the performance of the device.

Referring to FIGS. 1a to 1c, in some embodiments, a VCSEL is provided, which includes an N-type substrate 11 and an upper distributed Bragg reflector (DBR), and further includes an N-type buffer layer 12, a first tunnel junction 13, a P-type DBR 14, an active layer 15, a second tunnel junction 17, a P-type metal contact layer 18, and a cathode electrode 19, which are stacked sequentially along a direction perpendicular to the top surface (i.e., the front side) of the substrate 11 (e.g., in the oz-direction) and arranged on the front side of the substrate 11. The first tunnel junction 13 is configured to reverse N-type carriers in the N-type buffer layer 12 to P-type carriers. The second tunnel junction 17 is configured to reverse the carriers in the upper DBR to carriers of opposite conductivity type. The upper DBR is positioned between the active layer 15 and the P-type metal contact layer 18 and is associated with the second tunnel junction 17. An anode electrode 10 is arranged on a surface of the N-type substrate 11 away from the N-type buffer layer 12 (i.e., on a back side of the N-type substrate 11). In the embodiments of the present disclosure, the oz-direction is the positive direction of the z-axis, and is a direction perpendicular to the front side of the N-type substrate and pointing toward the first tunnel junction.

Exemplarily, referring further to FIG. 1a, the upper DBR is an N-type DBR 16 positioned between the active layer 15 and the second tunnel junction 17. The second tunnel junction 17 may be configured to reverse N-type carriers in the N-type DBR 16 to P-type carriers.

Exemplarily, referring to FIG. 1b, the upper DBR is a P-type distributed Bragg reflective layer 16m positioned between the second tunnel junction 17 and the P-type metal contact layer 18. The second tunnel junction 17 may be configured to reverse P-type carriers in the P-type distributed Bragg reflective layer 16m to N-type carriers to match the conductivity type of the active layer 15.

Exemplarily, referring further to FIG. 1c, the upper DBR includes an N-type distributed Bragg reflective sub-layer 161 and a P-type distributed Bragg reflective sub-layer 162. The N-type distributed Bragg reflective sub-layer 161 is positioned between the active layer 15 and the second tunnel junction 17. The P-type distributed Bragg reflective sub-layer 162 is positioned between the second tunnel junction 17 and the P-type metal contact layer 18. The second tunnel junction 17 may be configured to reverse N-type carriers in the N-type distributed Bragg reflective sub-layer 161 to P-type carriers.

Exemplarily, referring further to FIG. 1a, the N-type buffer layer 12, the first tunnel junction 13, the P-type DBR 14, the active layer 15, the N-type DBR 16, the second tunnel junction 17, the P-type metal contact layer 18, and the cathode electrode 19 are stacked sequentially along the direction away from the top surface of the substrate 11 and arranged on the front side of the substrate 11. The first tunnel junction 13 is adapted to reverse N-type carriers in the N-type buffer layer 12 to P-type carriers, and the second tunnel junction 17 is adapted to reverse the N-type carriers in the N-type DBR 16 to the P-type carriers, thereby allowing the anode electrode 20 to be arranged on the back side (i.e., the bottom surface) of the substrate 11 and the cathode electrode 19 to be arranged over the front side of the substrate 11, so that the N-type transistors having relatively high response speed are used to drive the light-emitting structure of the VCSEL, and that the common-anode driving mode is adopted to achieve a reduction in the volume of the driver system while improving the driving frequency and driving speed of the VCSEL.

Exemplarily, referring to FIGS. 1a to 1c, the N-type substrate 11 may be made of semiconductor material, insulative material, semi-insulative material, or any combination thereof. The N-type substrate 11 may be a single-layer structure or a multi-layer structure. For example, the N-type substrate 11 may be a gallium arsenide (GaAs) substrate, an indium phosphide (InP) substrate, any other III/V semiconductor substrate, or any other II/VI semiconductor substrate. The type of substrate should not limit the protection scope of the present disclosure. The N-type substrate 11 may include one or more of word lines, bit lines, and components such as transistors, which are omitted as they are not closely related to the key inventive aspects of this solution.

Exemplarily, referring further to FIGS. 1a to 1c, the word lines, the bit lines, and the components such as the transistors generally need to be fabricated in the N-type substrate 11. To reduce the lattice mismatch between the first tunnel junction 13 and the N-type substrate 11, or to reduce adverse effects on the first tunnel junction 13 caused by possible defects in the N-type substrate 11, the N-type buffer layer 12 is positioned between the N-type substrate 11 and the first tunnel junction 13, thereby effectively improving the yield and reliability of semiconductor device fabrication.

Exemplarily, referring to FIG. 1d, the active layer 15 includes an object stacked structure 150. The object stacked structure 150 includes a P-type semiconductor layer 1501, a quantum well layer 1502, and an N-type semiconductor layer 1503, which are sequentially stacked along the direction perpendicular to the top surface of the substrate 11 (e.g., in the oz-direction). The P-type semiconductor layer 1501 is adjacent to the P-type DBR 14. The quantum well layer 1502 includes at least one quantum well. The optical thickness of the active layer 15, the optical thickness of the P-type DBR 14, and the optical thickness of the upper DBR collectively define a wavelength of the resonant cavity of the VCSEL, which may be configured within an emission wavelength range of the active layer 15 to achieve a laser emission.

Exemplarily, a central cross-section of the quantum well region (i.e., a horizontal section of the quantum well region passing the center of the quantum well region) of the quantum well layer 1502 is positioned within an antinode region of a standing wave electric field of the VCSEL. z represents an antinode z-axial position, and the antinode region is [z−λ/8, z+λ/8], where λ represents the wavelength of a standing wave thereby avoiding the energy loss of internal layers as much as possible and enhancing the light emission efficiency and light emission quality of the VCSEL.

Exemplarily, the active layer 15 includes multiple object stacked structures 150 sequentially stacked along the direction perpendicular to the top surface of the substrate 11. Adjacent object stacked structures 150 are connected via an interlayer tunnel junction 151. In each two adjacent object stacked structures 150, the N-type semiconductor layer 1501 of one object stacked structure 150 is adjacent to the P-type semiconductor layer 1503 of the other object stacked structure 150. The wavelength of the resonant cavity of the VCSEL is set by configuring the optical thickness of the active layer 15 in combination with the optical thicknesses of the P-type DBR 14 and the upper DBR.

Exemplarily, the central cross-section of the interlayer tunnel junction 151 (i.e., a horizontal section of the interlayer tunnel junction 151 passing the center of the interlayer tunnel junction 151) is positioned within a node region of the standing wave electric field of the VCSEL. The central cross-section of the interlayer tunnel junction 151 is parallel to the substrate. p represents a node z-axial position, and the node region is [p−λ/8, p+λ/8], where λ represents the wavelength of a standing wave , thereby avoiding energy loss of internal layers as much as possible, improving the light emission efficiency and light emission quality of the VCSEL.

Exemplarily, referring further to FIGS. 1a to 1d, the central cross-section of the first tunnel junction 13 (i.e., a horizontal section of the first tunnel junction 13 passing the center of the first tunnel junction 13 and perpendicular to the oz-direction) is positioned within the node region of the standing wave electric field of the VCSEL. p represents the node z-axial position, and the node region is [p−λ/8, p+λ/8], where λ represents the wavelength of the standing wave, thus avoiding energy loss of the internal layers, and improving the light emission efficiency and light emission quality of the VCSEL.

In some embodiments, referring to FIG. 1e, the P-type DBR 14 may include stacked multiple first reflective layers 140. Each of the first reflective layers 140 includes a first reflective sub-layer 141 and a second reflective sub-layer 142 with different refractive indices. The first reflective sub-layer 141 in the P-type DBR 14 is adjacent to the substrate 11. In each two adjacent first reflective layers 140, the first reflective sub-layer 141 of one first reflective layer 140 and the second reflective sub-layer 141 of another first reflective layer 140 are adjacent. The material of the first reflective sub-layer 141 includes indium gallium phosphide, and the lattice constant of the compound in the second reflective sub-layer 142 is greater than that of indium gallium phosphide.

In some embodiments, referring to FIG. 1e, by configuring the first reflective sub-layer 141 to include indium gallium phosphide and the compound in the second reflective sub-layer 142 to have the lattice constant greater than that of the indium gallium phosphide, stresses in the first reflective layer 140 of the P-type DBR 14 can be counteracted with each other, thereby reducing a warpage. A conventional VCSEL can achieve very high reflectivity (99%) through a reflector of epitaxial layers, which are alternately formed by two materials with different refractive indices with a quarter-wavelength thick, which can meet special requirements of the device for the reflector. However, a lattice difference between the substrate 11 and the epitaxial layers causes a stress accumulation in the epitaxial layers. Additionally, too large an overall thickness of the epitaxial layers of the reflector leads to a large warpage of the epitaxial wafer, thus adversely affecting the yield of the semiconductor chip. Regarding the VCSEL provided in the embodiments of the present disclosure, the multiple first reflective layers are arranged and stacked in the P-type DBR 14, each of the first reflective layers including the first reflective sub-layer made of indium gallium phosphide and the second reflective sub-layer with different refractive indices, the first reflective sub-layer in the P-type DBR 14 being adjacent to the N-type substrate 11, the first reflective sub-layer and the second reflective sub-layer of the adjacent first reflective layers being adjacent, and the lattice constant of the compound in the second reflective sub-layer being greater than that of indium gallium phosphide, stresses among the respective reflective sub-layers in the P-type DBR 14 counteract with each other. This reduces the warpage and improves the yield of semiconductor chips. each of the first reflective layers 140 includes the first reflective sub-layer 141 made of indium gallium phosphide and the second reflective sub-layer, which have different refractive indices. The first reflective sub-layer 141 of the P-type DBR 14 is adjacent to the substrate 11. In each two adjacent first reflective layers 140, the first reflective sub-layer 141 of one first reflective layer 140 is adjacent to the second reflective sub-layer 142 of the other first reflective layer 140, and the lattice constant of the compound in the second reflective sub-layer 142 is greater than that of the indium gallium phosphide, so that stresses among the reflective sub-layers in the P-type DBR 14 can be counteracted by each other, thereby reducing the warpage and improving the yield of semiconductor chip.

In some embodiments, referring to FIG. 1e, the upper DBR includes stacked multiple second reflective layers 160. Each of the second reflective layer 160 includes a third reflective sub-layer 163 and a fourth reflective sub-layer 164 with different refractive indices. In each two adjacent second reflective layers 160, the third reflective sub-layer 163 of one second reflective layer 160 and the fourth reflective sub-layer 164 of the other second reflective layer 160 are adjacent. The materials of the third reflective sub-layer 163 and the fourth reflective sub-layer 164 each include aluminum gallium arsenide, and an aluminum composition in the third reflective sub-layer 163 and an aluminum composition in the fourth reflective sub-layer are different.

Exemplarily, the materials of the third reflective sub-layer 163 and the fourth reflective sub-layer 164 include AlₓGa₁₋ₓAs. The material AlₓGa₁₋ₓAs is formed by a uniform recombination of AlAs and GaAs, and has advantages such as high carrier mobility, adjustable aluminum composition, and minimal lattice mismatch with GaAs. The third reflective sub-layer 163 has the material Al ₓGa₁₋ₓAs, where x<0.1, while the fourth reflective sub-layer 164 has the material Al ₓGa₁₋ₓAs, where x>0.9. Alternating growth of the third reflective sub-layer 163 with high refractive indices and the fourth reflective sub-layer 164 with low refractive indices enables the number of the periods to be increased to achieve high reflectivity, thereby meeting the specific requirements of the VCSEL structure for reflectors.

In some embodiments, the material of the first reflective sub-layer 141 includes In_{y}Ga_{1-y}P, where y∈ [0, 0.48]. For example, y may be set to be 0, 0.1, 0.15, 0.2, 0.25, 0.3, 0.35, 0.4, or 0.48, etc.

In some embodiments, the material of the second reflective sub-layer 142 includes aluminum arsenide or aluminum gallium arsenide.

Exemplarily, the material of the first reflective sub-layer may be In_{0.48}Ga_{0.52}P, and the material of the substrate 11 may be GaAs. The lattice constant of In_{0.48}Ga_{0.52}P is smaller than that of the substrate 11 made of GaAs, and the first reflective sub-layer 141 subjects to tensile stresses. The material of the second reflective sub-layer 142 includes AlₓGa₁₋ₓAs, where it is usually satisfied that x>0.9. The second reflective sub-layer 142 has a lattice constant greater than that of In_{0.48}Ga_{0.52}P, and subjects to pressive stresses. Thus, the tensile and pressive stresses within each DBR period (i.e., in each first reflective layer 140) are counteracted by each other, thereby reducing the warpage of the epitaxial wafer.

Specifically, for a VCSEL with the wavelength of 940 nm, the refractive index difference between AlGaAs having a high aluminum composition and AlGaAs having a low aluminum composition is about 0.465, while the refractive index difference between In_{0.48}Ga_{0.52}P and AlGaAs is about 0.246. To obtain a sufficient reflectivity, the DBR made of the material InGaP can achieve low warpage while allowing for a relatively large thickness of the DBR.

In some embodiments, a laser array is provided. The laser array includes multiple VCSELs according to any of the above embodiments, which are arranged in rows and columns. VCSELs in the same row are all connected to a corresponding row selection line. VCSELs in the same column are all connected to a corresponding column selection line. VCSELs in different rows are connected to different row selection lines respectively. VCSELs in different columns are connected to different column selection lines respectively. By selecting a row selection line and a column selection line, a VCSEL connected to both the selected row selection line and column selection line is activated, thereby realizing a common-anode driving mode. In addition, an N-type transistor having a relatively high response speed is used to drive the light-emitting structure of the VCSEL, thereby increasing the driving frequency and driving speed of the VCSEL while reducing the size of the driver system. By configuring that the VCSELs in the same row are all connected to the corresponding row selection line, the VCSELs in the same column are all connected to the corresponding column selection line, the VCSELs in different rows are connected to different row selection lines respectively, and the VCSELs in different columns are connected to different column selection lines respectively, it can be realized that, when a certain VCSEL fails, the faulty laser can be quickly located, thereby improving the operation efficiency of the device.

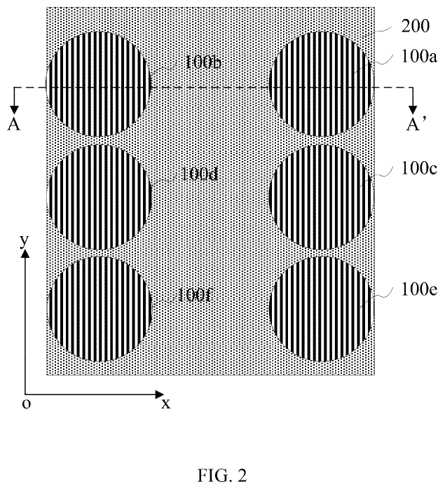

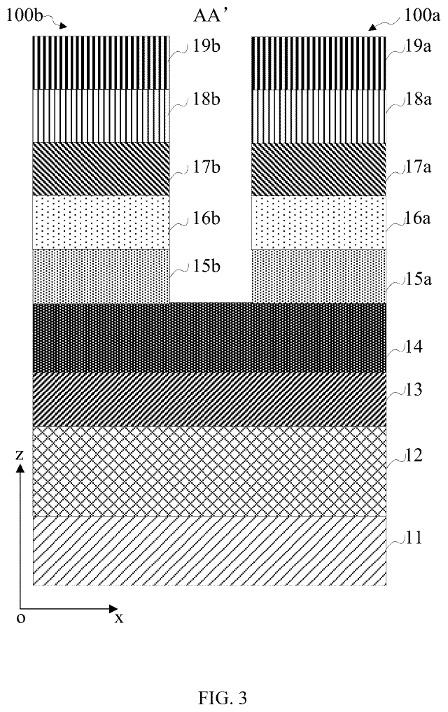

Exemplarily, referring to FIG. 2 and FIG. 3, a first VCSEL 100a, a second VCSEL 100b, a third VCSEL 100c, a fourth VCSEL 100d, a fifth VCSEL 100e, and a sixth VCSEL 100f, which are arranged in rows and columns, share an anode electrode. Among the first VCSEL 100a, the second VCSEL 100b, the third VCSEL 100c, the fourth VCSEL 100d, the fifth VCSEL 100e, and the sixth VCSEL 100f, the cathode electrodes of adjacent VCSELs are insulative to each other. Therefore, it is realized that the cathode electrodes of different VCSELs are driven independently in the case where the anode driving is simplified, thereby meeting the driving control requirements for customized light emission schemes of the laser array.

Exemplarily, an isolation structure is arranged between adjacent VCSELs, and the isolation structure extends in a direction perpendicular to the substrate (e.g., in the oz-direction) to the top surface of the first DBR, thereby avoiding a mutual interference between adjacent VCSELs while simplifying the structure and fabrication process of the laser array.

Exemplarily, referring further to FIG. 3, the isolation structure may be an isolation trench. The isolation trench is arranged between the first VCSEL 100a and the second VCSEL 100b, and extends in the direction perpendicular to the substrate (e.g., in the oz-direction) to the top surface of the P-type DBR 14. The active layer 15a, the N-type DBR 16a, the second tunnel junction 17a, the P-type metal contact layer 18a, and the cathode electrode 19a of the first VCSEL 100a are electrically isolated from the active layer 15b, the N-type DBR 16b, the second tunnel junction 17b, the P-type metal contact layer 18b, and the cathode electrode 19b of the second VCSEL 100b respectively by the isolation trench. The first VCSEL 100a and the second VCSEL 100b share the N-type substrate 11, the N-type buffer layer 12, the first tunnel junction 13, and the P-type DBR 14.

In some embodiments, a light-emitting device is provided, including the VCSEL according to any one of the above embodiments.

In some embodiments, a light-emitting device is provided, including the laser array according to any one of the above embodiments.

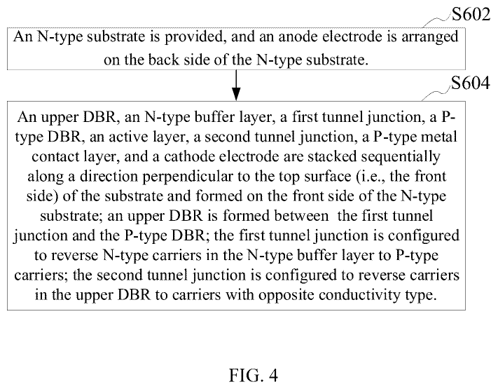

Exemplarily, referring to FIG. 4, a method for fabricating a VCSEL is provided, including step S602 and step S604.

At step S602, an N-type substrate is provided, and an anode electrode is arranged on the back side of the N-type substrate.

At step S604, an upper DBR, an N-type buffer layer, a first tunnel junction, a P-type DBR, an active layer, a second tunnel junction, a P-type metal contact layer, and a cathode electrode are stacked sequentially along a direction perpendicular to the top surface (i.e., the front side) of the substrate and formed on the front side of the N-type substrate; an upper DBR is formed between the first tunnel junction and the P-type DBR; the first tunnel junction is configured to reverse N-type carriers in the N-type buffer layer to P-type carriers; the second tunnel junction is configured to reverse carriers in the upper DBR to carriers of opposite conductivity type.

Exemplarily, referring further to FIG. 1a, the N-type buffer layer, the first tunnel junction, the P-type DBR, the active layer, the N-type DBR, the second tunnel junction, the P-type metal contact layer, and the cathode electrode are stacked sequentially along the direction away from the top surface of the substrate. The first tunnel junction is adapted to reverse the N-type carriers in the N-type buffer layer to the P-type carriers, and the second tunnel junction is adapted to reverse the N-type carriers in the N-type DBR to the P-type carriers, thereby allowing the anode electrode to be arranged on the back side (i.e., the bottom surface) of the substrate and the cathode electrode to be arranged over the front side of the substrate, so that the N-type transistors having relatively high response speed are used to drive the light-emitting structure of the VCSEL, and that the common-anode driving mode is adopted to achieve a reduction in the volume of the driver system while improving the driving frequency and driving speed of the VCSEL.

It should be understood that although the steps in the flowchart of FIG. 4 are shown sequentially according to indications of arrows, these steps are not necessarily performed in the order indicated by the arrows. Unless otherwise explicitly stated herein, there are no strict sequence constraints for performing these steps, and these steps may be performed in other orders. In addition, at least some of the steps in FIG. 4 may include multiple steps or stages. These steps or stages are not necessarily performed at the same time but may be performed at different times, and these sub-steps or stages are not necessarily performed in sequence, but may be performed alternating or in turn with other steps or at least part of the steps or stages in other steps.

Note that the above embodiments are used for illustrative purposes only but not intended to limit the present disclosure.

The embodiments in this specification are described progressively. Each embodiment focuses on its differences from other embodiments, while similar aspects across embodiments may be cross-referenced.

The technical features of the above embodiments can be combined arbitrarily. For concise description, not all possible combinations of the technical features in the above embodiments are described. However, as long as there is no contradiction in the combination of these technical features, these combinations should be considered within the scope recorded in this specification.

The above embodiments are merely some implementations of the present disclosure, they are described relatively specifically and in detail, but should not be construed as limiting the scope of this patent application. It should be pointed out that for those skilled in the art, several modifications and improvements can be made without departing from the inventive concepts of the present disclosure, and these modifications and improvements all fall within the protection scope of the present disclosure. Therefore, the protection scope of the present disclosure shall be subject to the appended claims.

What is claimed is:

1. A vertical-cavity surface-emitting laser (VCSEL), comprising an N-type substrate, an upper distributed Bragg reflector (DBR), an N-type buffer layer, a first tunnel junction, a P-type DBR, an active layer, a second tunnel junction, a P-type metal contact layer, and a cathode electrode; wherein
the N-type buffer layer, the first tunnel junction, the P-type DBR, the active layer, the second tunnel junction, the P-type metal contact layer, and the cathode electrode are stacked sequentially along a direction perpendicular to a front side of the N-type substrate and arranged on the front side of the N-type substrate;
the first tunnel junction is configured to reverse carriers in the N-type buffer layer to carriers of opposite conductivity type;
the second tunnel junction is configured to reverse carriers in the upper DBR to carriers of opposite conductivity type;
the upper DBR is positioned between the active layer and the P-type metal contact layer and associated with the second tunnel junction; and
an anode electrode is arranged on a back side of the N-type substrate away from the N-type buffer layer.

2. The VCSEL according to claim 1, wherein the active layer includes an object stacked structure;
the object stacked structure comprises a P-type semiconductor layer, a quantum well layer, and an N-type semiconductor layer sequentially stacked along the direction perpendicular to the front side the N-type substrate; the P-type semiconductor layer is adjacent to the P-type DBR; and
the quantum well layer comprises at least one quantum well.

3. The VCSEL according to claim 1, wherein a central cross-section of the first tunnel junction is positioned within a node region of a standing wave electric field of the VCSEL; and
the node region is [p−λ/8, p +λ/8], wherein p represents a node z-axial position, λ represents a wavelength of a standing wave, and a positive direction of a z-axis is a direction perpendicular to the front side of the N-type substrate and pointing toward the first tunnel junction.

4. The VCSEL according to claim 2, wherein a central cross-section of a quantum well region of the quantum well layer is positioned within an antinode region of a standing wave electric field of the VCSEL; and
the antinode region is [z−λ/8, z+λ/8], wherein z represents an antinode z-axial position, λ represents a wavelength of a standing wave, and a positive direction of a z-axis is a direction perpendicular to the front side of the N-type substrate and pointing toward the first tunnel junction.

5. The VCSEL according to claim 2, wherein the active layer comprises a plurality of object stacked structures sequentially stacked along the direction perpendicular to the front side of the N-type substrate;
adjacent object stacked structures are connected via an interlayer tunnel junction; and
in each two adjacent object stacked structures, the N-type semiconductor layer of one object stacked structure is adjacent to the P-type semiconductor layer of the other object stacked structure.

6. The VCSEL according to claim 5, wherein a central cross-section of the interlayer tunnel junction is positioned within the node region of the standing wave electric field of the VCSEL; the central cross-section of the interlayer tunnel junction is parallel to the top surface of the substrate; and
the node region is [p−λ/8, p +λ/8], wherein p represents a node z-axial position, λ represents a wavelength of a standing wave, and a positive direction of a z-axis is a direction perpendicular to the front side of the N-type substrate and pointing toward the first tunnel junction.

7. The VCSEL according to claim 1, wherein
the upper DBR is a P-type distributed Bragg reflective layer positioned between the second tunnel junction and the P-type metal contact layer; or
the upper DBR is an N-type DBR positioned between the active layer and the second tunnel junction.

8. The VCSEL according to claim 7, wherein
the upper DBR comprises stacked multiple second reflective layers;
each of the multiple second reflective layers comprises a third reflective sub-layer and a fourth reflective sub-layer with different refractive indices; and
in each two adjacent second reflective layers, the third reflective sub-layer of one second reflective layer and the fourth reflective sub-layer of the other second reflective layer are adjacent.

9. The VCSEL according to claim 8, wherein material of each third reflective sub-layer and material of each fourth reflective sub-layer comprise aluminum gallium arsenide, and an aluminum composition in each third reflective sub-layer and an aluminum composition in each fourth reflective sub-layer are different.

10. The VCSEL according to claim 9, wherein
the material of each third reflective sub-layer is AlₓGa₁₋ₓAs, wherein x<0.1; and
the material of each fourth reflective sub-layer is AlₓGa₁₋ₓAs, wherein x>0.9.

11. The VCSEL according to claim 1, wherein the upper DBR comprises:
an N-type distributed Bragg reflective sub-layer positioned between the active layer and the second tunnel junction; and
a P-type distributed Bragg reflective sub-layer positioned between the second tunnel junction and the P-type metal contact layer.

12. The VCSEL according to claim 1, wherein
the P-type DBR comprises stacked multiple first reflective layers;
each of the multiple first reflective layers comprises a first reflective sub-layer and a second reflective sub-layer with different refractive indices; and
in each two adjacent first reflective layers, the first reflective sub-layer of one first reflective layer and the second reflective sub-layer of the other first reflective layer are adjacent.

13. The VCSEL according to claim 12, wherein a material of each first reflective sub-layer comprises indium gallium phosphide, and a lattice constant of compound in each second reflective sub-layer is greater than a lattice constant of the indium gallium phosphide.

14. The VCSEL according to claim 13, wherein
the material of each first reflective sub-layer comprises In_{y}Ga_{1-y}P, wherein y∈ [0, 0.48]; and
the material of each second reflective sub-layer comprises AlₓGa₁₋ₓAs, wherein x>0.9

15. The VCSEL according to claim 1, wherein the N-type substrate is made of semiconductor material, insulative material, semi-insulative material, or any combination thereof.

16. A laser array, comprising a plurality of VCSELs of claim 1 arranged in rows and columns, wherein
VCSELs in the same row are connected to a corresponding row selection line;
VCSELs in the same column are connected to a corresponding column selection line;
VCSELs in different rows are connected to different row selection lines, respectively;
VCSELs in different columns are connected to different column selection lines, respectively; and
a VCSEL connected to a selected row selection line and a selected column selection line is activated by selecting the row selection line and the column selection line.

17. The laser array according to claim 16, wherein the plurality of VCSELs arranged in rows and columns share an anode electrode;
wherein cathode electrodes of any adjacent VCSELs are insulative to each other.

18. The laser array according to claim 17, wherein an isolation structure is arranged between the adjacent VCSELs, and the isolation structure is adapted to extend in the direction perpendicular to the front side of the N-type substrate to the top surface of the P-type DBR.

19. A light-emitting device, comprising the VCSEL of claim 1.

20. A light-emitting device, comprising the laser array of claim 16.
